(19) United States
(12) Patent Application Publication
(10) Pub. No.: US 2014/0085845 A1
(43) Pub. Date: Mar. 27, 2014

(54) THICK-FILM HYBRID CIRCUIT STRUCTURE AND METHOD OF MANUFACTURE THE SAME

(71) Applicants: AMBIT MICROSYSTEMS (ZHONGSHAN) LTD., Zhongshan (CN); HON HAI PRECISION INDUSTRY CO., LTD., New Taipei (TW)

(72) Inventors: HONG-GUANG HUANG, Shenzhen (CN); SHUN-LONG LEE, New Taipei (TW)

(73) Assignees: HON HAI PRECISION INDUSTRY CO., LTD., New Taipei (TW); AMBIT MICROSYSTEMS (ZHONGSHAN) LTD., Zhongshan (CN)

(21) Appl. No.: 13/784,852

(22) Filed: Mar. 5, 2013

(30) Foreign Application Priority Data
Sep. 27, 2012 (CN) 2012103653388

(51) Int. Cl. H05K 1/18; H05K 3/36

(52) U.S. Cl. CPC H05K 1/182; H05K 3/36
USPC 361/761; 228/176

(57) ABSTRACT

A thick-film hybrid circuit structure includes a first thick-film substrate, a second thick-film substrate stacked on the first thick-film substrate and electrically connected to the first thick-film substrate, a chip and an encapsulation body. The second thick-film substrate defines a receiving area, and the chip is fixed in the receiving area and electrically connected to the first thick-film substrate.

### BACKGROUND

1. Technical Field

The present disclosure generally relates to thick-film hybrid circuit structures and methods for manufacturing the same, and more particularly to a thick-film hybrid circuit structure with two stacked ceramic layers.

2. Description of Related Art

Generally, a thick-film hybrid circuit structure includes a substrate, a first conductive layer printed on the substrate, an insulating ink layer printed on the first conductive layer, and a second conductive layer printed on the insulating ink layer. Because the insulating ink layer must completely cover the first conductive layer with a large area, it is prone to produce cavities in the insulating ink layer. So there is a risk that a short circuit may be generated between the first conductive layer and the second conductive layer. Furthermore, a distributed capacitance exists between the two conductive layers due to the insulating ink layer, which weakens signal transmission quality of the thick-film hybrid circuit structure.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic perspective view of a thick-film hybrid circuit structure of an exemplary embodiment of the disclosure.

FIG. 2 is an exploded view of the thick-film hybrid circuit structure of FIG. 1.

FIG. 3 is a flowchart of a fabricating method of the thick-film hybrid circuit structure of an exemplary embodiment of the disclosure.

FIG. 4 is a schematic view of printing a first circuit on a first ceramic layer to form a first thick-film substrate.

FIG. 5 is a schematic view of printing a second circuit on a second ceramic layer to form a second thick-film substrate.

FIG. 6 is a schematic view of defining a plurality of vias and a receiving area in the second thick-film substrate.

FIG. 7 is a schematic view of printing conductive material on the first thick-film substrate.

FIG. 8 is a schematic view of combining the first thick-film substrate and the second thick-film substrate.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

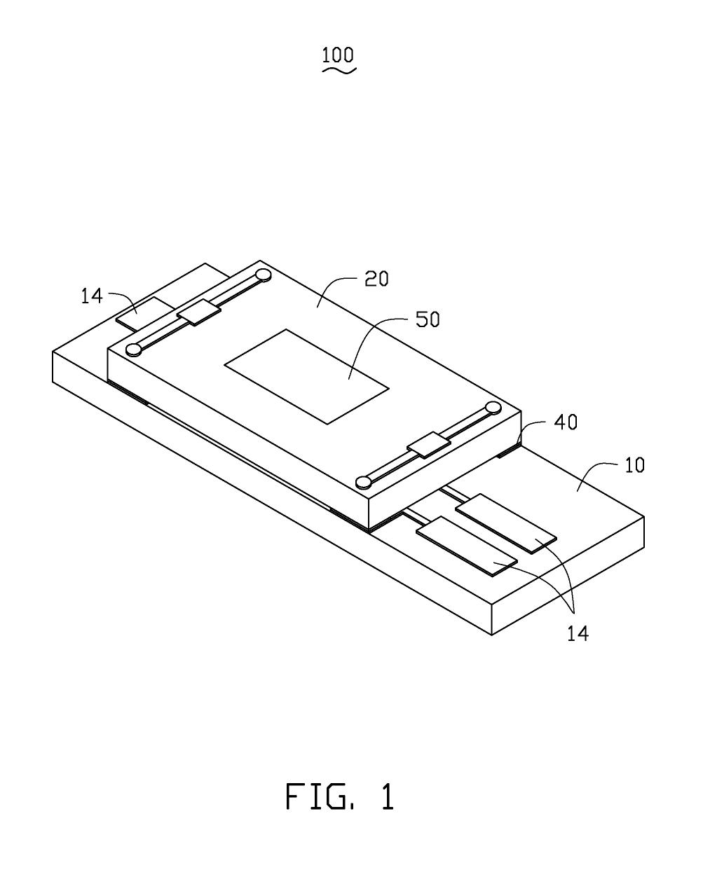

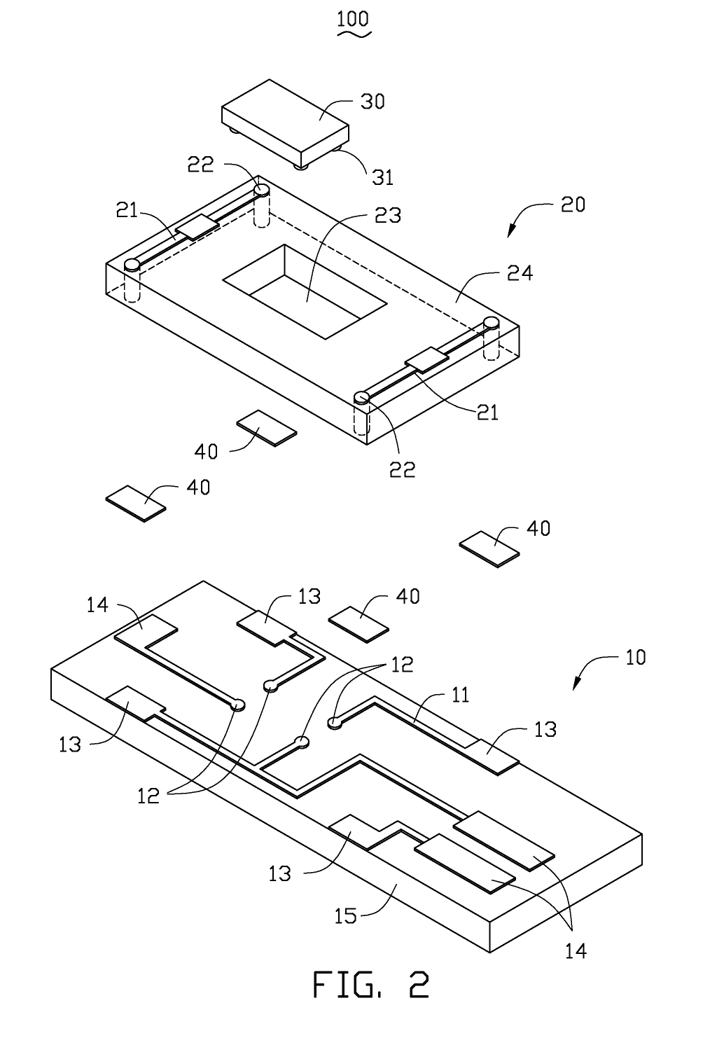

With reference to FIG. 1 and FIG. 2, a thick-film hybrid circuit structure 100 includes a first thick-film substrate 10, a second thick-film substrate 20 stacked on the first thick-film substrate 10 and electrically connected to the first thick-film substrate 10, a chip 30, and an encapsulating body 50. The second thick-film substrate 20 defines a receiving area 23 receiving the chip 30. The chip 30 is fixed in the receiving area 23 by the encapsulating body 50 and electrically connected to the first thick-film substrate 10.

The first thick-film substrate 10 includes a first ceramic layer 15, a first circuit 11, a plurality of first solder pads 12, a plurality of second solder pads 13, and a plurality of third solder pads 14 located at two ends of the first ceramic layer 15. All of the pads 12, 13, 14 are electrically connected to the first circuit 11. Each of the plurality of second solder pads 13 is covered by conductive material 40. In the embodiment, the conductive material 40 may be made of conductive printing ink. Alternatively, the conductive material 40 may be made of solder tin.

The second thick-film substrate 20 includes a second ceramic layer 24, a second circuit 21 printed on the second ceramic layer 24, and a plurality of vias 22 electrically connected to the second circuit 21. Each of the plurality of vias 22 is filled with filling material. The second ceramic layer 24 defines a receiving area 23.

In assembly, the second thick-film substrate 20 is stacked on the first thick-film substrate 10 with the plurality of second solder pads 13 opposite to the plurality of vias 22 of the second thick-film substrate 20, and the first thick-film substrate 10 is electrically connected to the second thick-film substrate 20 by the conductive material 40 covering on the plurality of second solder pads 13. Projections of the plurality of first solder pads 12 of the first thick-film substrate 10 on the second thick-film substrate 20 are surrounded by the receiving area 23 of the second thick-film substrate 20. The chip 30 is fixed in the receiving area 23 of the second thick-film substrate 20 by the encapsulating body 50 with a plurality of pins 31 on a bottom of the chip 30 contacting the plurality of first solder pads 12 of the first thick-film substrate 10, as a result, the chip 30 is electrically connected to the first thick-film substrate 10. The plurality of third solder pads 14 are exposed on the second thick-film substrate 20 to electrically connect to an exterior circuit.

In the embodiment, the plurality of third solder pads 14 are printed on the first ceramic layer 15. Alternatively, the plurality of third solder pads 14 can be printed on the second ceramic layer 24 according to practical requirements.

The thick-film hybrid circuit structure 100 of the disclosure includes the first thick-film substrate 10 and the second thick-film substrate 20 stacked on the first thick-film substrate 10 and electrically connected to the first thick-film substrate 10 by the conductive material 40, which can effectively prevent a short circuit to be formed between the two thick-film substrates 10, 20, and improve signal transmission quality of the thick-film hybrid circuit structure 100. Because the first and second circuits 11, 21 are printed on two different ceramic layers 15, 24, the signals of the two thick-film substrates 10, 20 are isolated from each other. In addition, the chip 30 is fixed in the receiving area 23 of the second thick-film substrate 20, which leads to a small size of a product using the thick-film hybrid circuit structure 100, due to reduction of the height of the thick-film hybrid circuit structure 100.

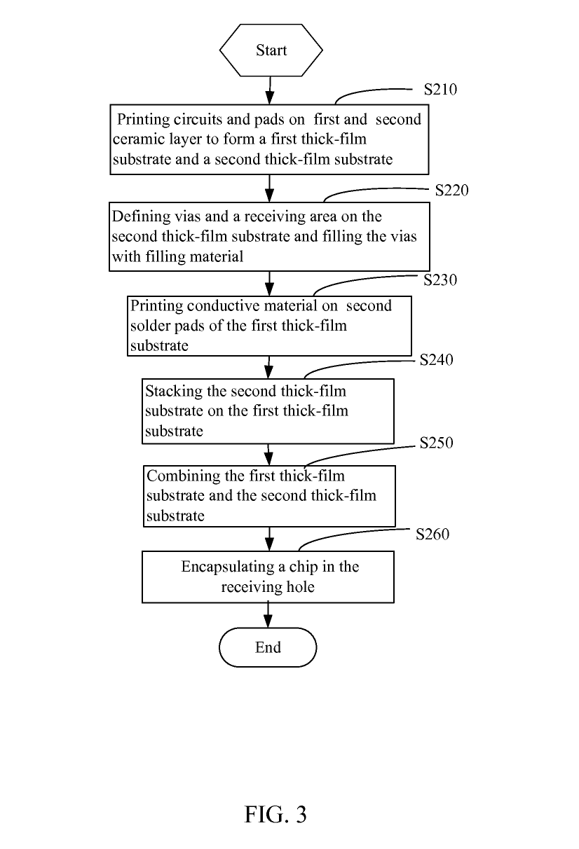

FIG. 3 is a flow chart of a fabricating method of the thick-film hybrid circuit structure 100 of an exemplary embodiment of the disclosure. The fabricating method of the thick-film hybrid circuit structure 100 includes steps as follow.

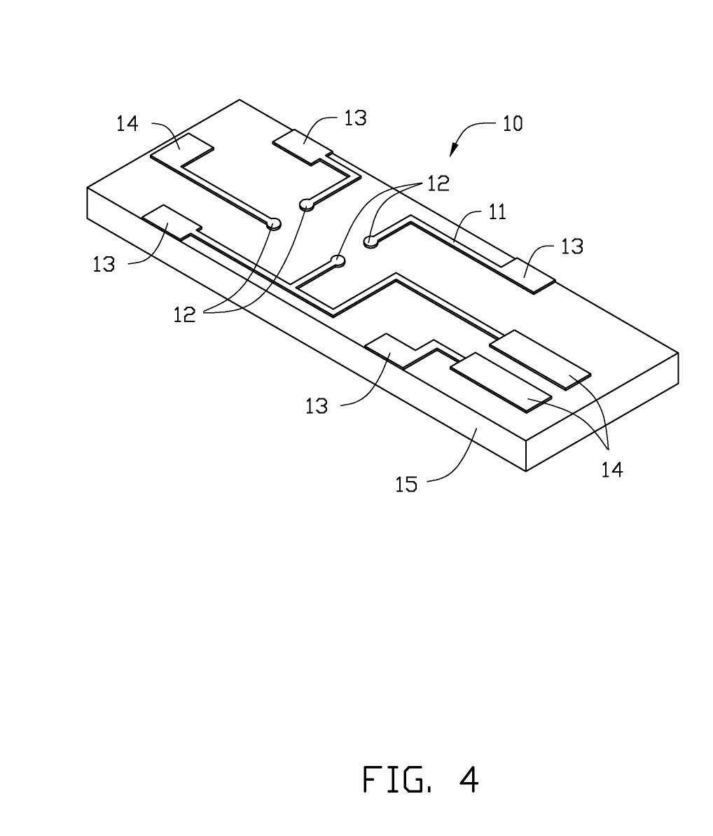

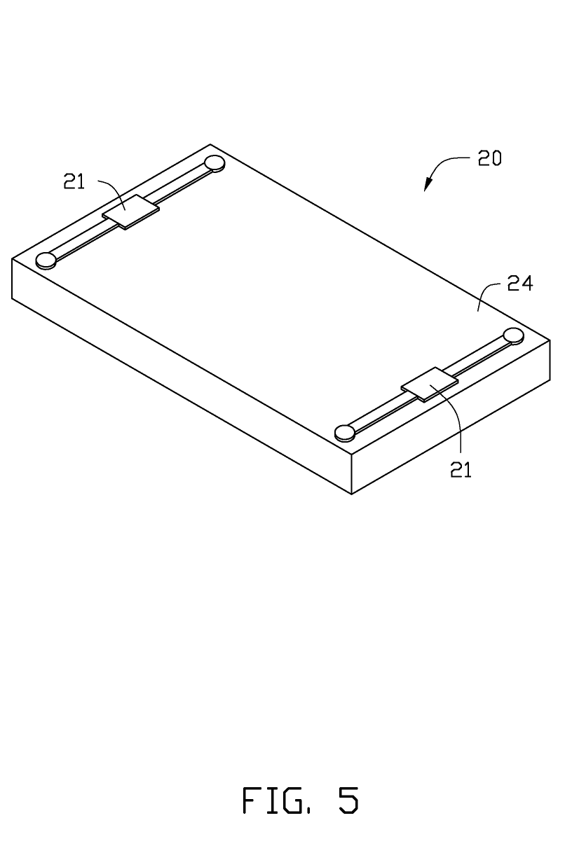

With reference to FIG. 4 and FIG. 5, in step S210, the circuits 11, 21 and pads 12, 13, 14 are printed on the first ceramic layer 15 and the second ceramic layer 24 by thick film technology. In detail, the first circuit 11, the plurality of first solder pads 12, the plurality of second solder pads 13 and the plurality of third solder pads 14 are printed on the first ceramic layer 15 to form a first thick-film substrate 10, and the second circuit 21 is printed on the second ceramic layer 24 to form a second thick-film substrate 20.

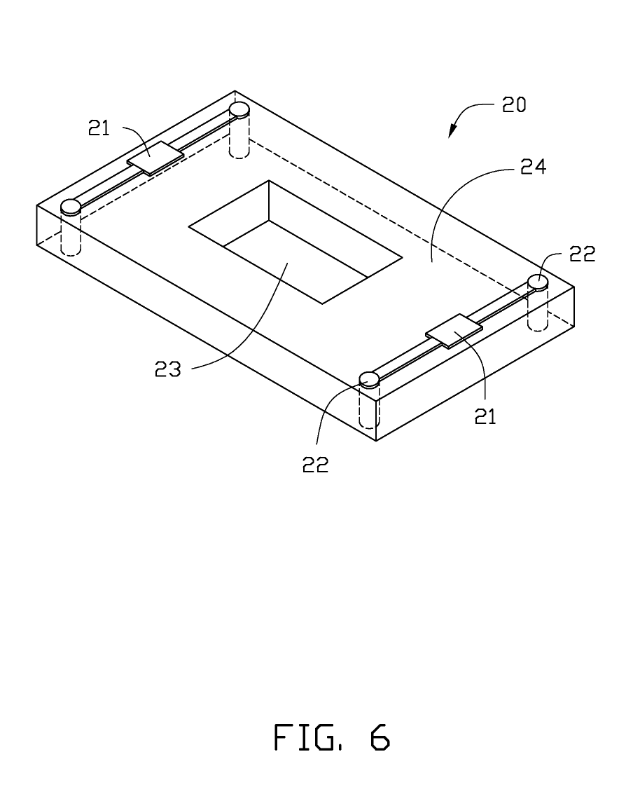

With reference to FIG. 3 and FIG. 6, in step S220, the receiving area 23 and the plurality of vias 22 are formed on the second thick-film substrate 20 and each of the plurality of vias 22 is filled with the filling material. In the embodiment, the receiving area 23 and the plurality of vias 22 may be formed on the second thick-film substrate 20 by a mechanical drilling process. Alternatively, the receiving area 23 and the plurality of vias 22 may be formed on the second thick-film substrate 20 by an etching process.

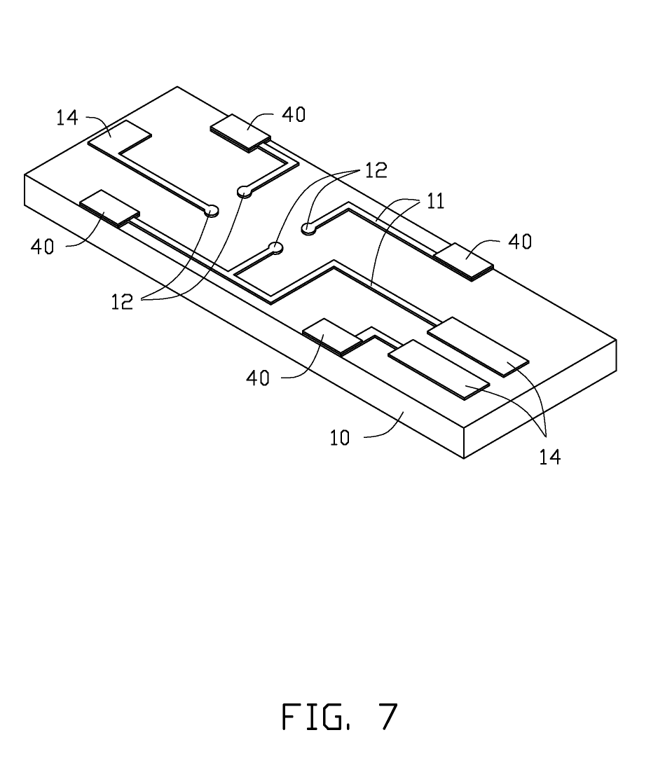

With reference to FIG. 3 and FIG. 7, in step S230, the conductive material 40 is printed on the second solder pad 13 of the first thick-film substrate 10.

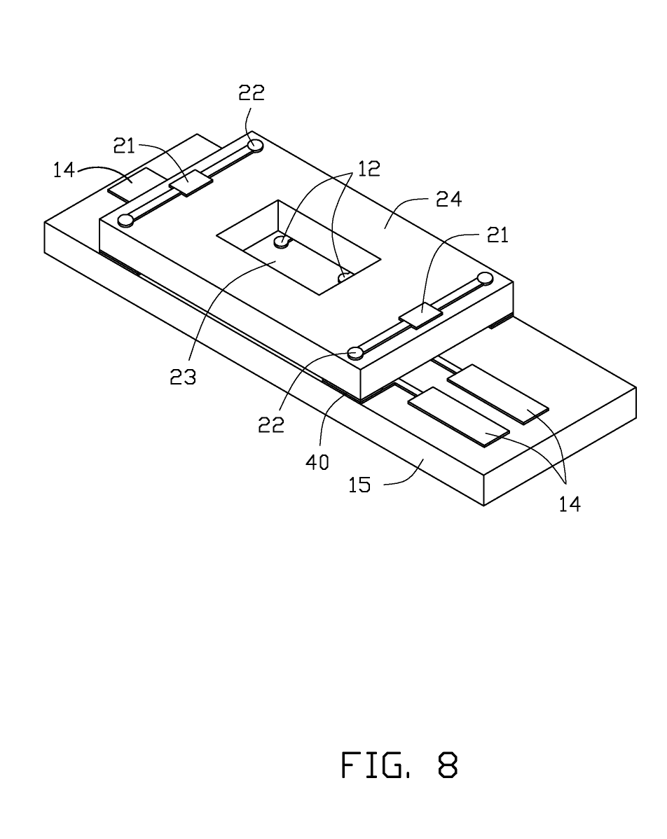

With reference to FIG. 3 and FIG. 8, in step S240, the second thick-film substrate 20 is stacked on the first thick-film substrate 10 with the second solder pad 13 of the first thick-film substrate 10 electrically connected to the plurality of vias 22 of the second thick-film substrate 20. In the embodiment, the second thick-film substrate 20 stacks on the first thick-film substrate 10 with the plurality of second solder pads 13 of the first thick-film substrate 10 opposite to the plurality of vias 22 of the second thick-film substrate 20. Projections of the plurality of first solder pads 12 of the first thick-film substrate 10 on the second thick-film substrate 20 are surrounded by the receiving area 23 of the second thick-film substrate 20. The first thick-film substrate 10 and the second thick-film substrate 20 are electrically connected to each other by the conductive material 40 on the plurality of the second solder pads 13.

In step S250, the first thick-film substrate 10 is combined with the second thick-film substrate 20. If the conductive material 40 on the plurality of the second solder pads 13 is made of conductive printing ink, the first thick-film substrate 10 is fixed with the second thick-film substrate 20 by a firing process. If the conductive material 40 on the plurality of the second solder pads 13 is made of solder tin, the first thick-film substrate 10 is fixed with the second thick-film substrate 20 by a reflowing soldering process.

In process S260, the chip 30 is received/encapsulated in the receiving area 23 of the second thick-film substrate 20 with the plurality of pins 31 on the bottom of the chip 30 electrically connected to the plurality of first solder pads 12 of the first thick-film substrate 10, and the chip 30 is fixed in the receiving area 23 of the second thick-film substrate 20 by the encapsulating body 50 under a molding process.

The fabricating method of the thick-film hybrid circuit structure 100 of the disclosure can improve circuit integration of the thick-film hybrid circuit structure 100. In addition, the chip 30 is received in the receiving area 23 of the second thick-film substrate 20, which protects the chip 30 from damages during a production process of the product using the thick-film hybrid circuit structure 100, and can prevent the encapsulating body 50 spilling over the thick-film hybrid circuit structure 100 during the molding process.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A thick-film hybrid circuit structure, comprising:
a first thick-film substrate;
a second thick-film substrate stacked on the first thick-film substrate and electrically connected to the first thick-film substrate, a chip; and
an encapsulation body, the second thick-film substrate defining a receiving area, and the chipfixed in the receiving area and electrically connected to the first thick-film substrate.

2. The thick-film hybrid circuit structure of claim 1, wherein the first thick-film substrate comprises a first ceramic layer, a first circuit on the first ceramic layer, a plurality of first solder pads, and a plurality of second solder pads, wherein the plurality of first solder pads and the plurality of second solder pads are electrically connected to the first circuit.

3. The thick-film hybrid circuit structure of claim 2, wherein the second thick-film substrate comprises a second ceramic layer and a second circuit on the second ceramic layer, and defines a plurality of vias electrically connected to the second circuit, wherein the chip is electrically connected to the plurality of first solder pads, and the plurality of second solder pads are electrically connected to the plurality of vias.

4. The thick-film hybrid circuit structure of claim 2, wherein the first thick-film substrate comprises a third solder pad exposed on the second thick-film substrate.

5. The thick-film hybrid circuit structure of claim 2, wherein each of the plurality of second solder pads is covered by conductive material.

6. The thick-film hybrid circuit structure of claim 5, wherein the conductive material is made of conductive printing ink.

7. The thick-film hybrid circuit structure of claim 5, wherein the conductive material is made of solder tin.

8. A fabrication method of a thick-film hybrid circuit structure comprising:
printing a first circuit, a plurality of first solder pads, and a plurality of second solder pads on a first ceramic layer to form a first thick-film substrate;
printing a second circuit on a second ceramic layer to form a second thick-film substrate;
defining a plurality of vias and a receiving area on the second thick-film substrate and filling the plurality of vias with filling material;
printing conductive material on each of the plurality of second solder pads of the first thick-film substrate;
stacking the second thick-film substrate on the first thick-film substrate with the plurality of second solder pads of the first thick-film substrate electrically connected with the plurality of vias of the second thick-film substrate;
combining the first thick-film substrate and the second thick-film substrate; and
encapsulating a chip in the receiving area with the chip electrically connected to the first thick-film substrate.

9. The fabrication method of the thick-film hybrid circuit structure of claim 8, wherein the conductive material is made of solder tin.

10. The fabrication method of the thick-film hybrid circuit structure of claim 8, wherein the conductive material is made of conductive printing ink.

11. The fabrication method of the thick-film hybrid circuit structure of claim 8, wherein the second thick-film substrate is combined with the first thick-film substrate by a reflowing soldering process.

12. The fabrication method of the thick-film hybrid circuit structure of claim 8, wherein second thick-film substrate is combined with the first thick-film substrate by a firing process.
